(19) United States
(12) Patent Application Publication
(10) Pub. No.: US 2007/0064841 A1
(43) Pub. Date: Mar. 22, 2007

(54) Method for producing a contact-fastening part

(76) Inventors: Jan Tuma, Herrenberg-Monchberg (DE); Ingo Gerber, Weil im Schonbuch (DE)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/557,990

(22) PCT Filed: Apr. 7, 2004
(86) PCT No.: PCT/EP04/03735

§ 371 Date: Nov. 22, 2005

(30) Foreign Application Priority Data
May 27, 2003 (DE) 10325372.6

(51) Int. Cl. H03D 1/00

(52) U.S. Cl. 375/341

(57) ABSTRACT

The invention relates to a method for producing a contact-fastener part, according to which a support (10) is manufactured with a plurality of columns (12), the latter being preferably produced as one-piece with the support. On said contact-fastener part, at least some of the free ends of the columns (12) are provided with a plurality of individual filaments (14).

The invention relates to a method for producing a contact-fastener part in which a support is manufactured to have a plurality of stalks preferably integrated with it.

A process such as this is known from the prior art, especially from PCT/WO 94/23610. The formation of a contact-fastener part for baby diapers or for hospital clothing is disclosed as a potential application of a contact-fastener part produced in this manner. Production of contact-fastener parts which may be used in articles of clothing such as these requires a relatively large number of interlocking means per square centimeter, something which results in correspondingly high production costs in that the molding roller used in the prior art must have a corresponding number of open cavities which must be impressed in an intricate process. The contact-fastener parts produced in this way have integrated with it on a sheet-like support material vertically projecting stalks provided on their free ends with a head enlargement which work in conjunction with a corresponding fleece or looped material which interlocks mechanically with the lower side of the head-like enlargement of the stalk material. Such fastener systems are also marketed in German-speaking areas under the trade name Velcro7 fasteners.

These hook and loop fastener systems of the prior art exhibit the disadvantage that for effective engagement, that is, formation of the contact fastening proper, they must always work with corresponding fastener parts (fleece or loop material). Modem fastener systems currently also afford the possibility of interconnecting identically configured head fastener parts to form the fastener; the ends on the head side of one fastener part enter the spaces between the ends and the stalks on the head side of the other fastener part and the head elements extend radially in relation to the stalks being engaged with each other by the edge surfaces facing each other. It is also possible to configure the respective fastening systems to be separable.

Processes for manufacture of fibrillated foils of propylene or polyethylene are also known in the prior art (DE 198 37 499 A1, U.S. Pat. No. 6,432,347 B1), processes in which the existing plant technologies (sheet extrusion facilities for flat foil, and sheet foil production or for application of chill roll processes) apply special measures in the technology and at the plants for stretching, fibrillation, and coiling of sheets without division into strips, and in this way netted foil of varying width and great length may be produced. The monoaxial stretching in this disclosed solution results in improved molecular orientation of the fibers and the fabrics produced in this manner are employed as geotextiles or in construction as reinforcement material. In addition, German Patent Application 1 175 385 and U.S. Pat. No. 6,432,347 describe fibrillation of foil material by use of a swirl nozzle or a pulsed stream of water under high pressure in order to obtain filter material possessing improved thermal and acoustic insulation properties.

On the basis of this prior art the object of the invention is further improvement in the disclosed process in order to obtain a contact-fastener part which is both reliable in use and cost effective in production and permits a broader selection of associated components with which the contact-fastener part claimed for the invention can form a reliable contact fastening. The object as thus formulated is attained by a process having the characteristics specified in claim 1 in its entirety.

In that, as specified in the characterizing part of claim 1, in the contact-fastener part at least some of the free ends of the stalk are provided with a plurality of individual fibers, the possibility is created of selecting a very thin diameter for the respective fibers so that only a very small contact surface, one preferably configured to be flat, for example, one of 0.2 to 0.5 μm, is available. In preferred embodiments the thickness of these structures may lie in the nanometer range, such as 200 to 500 nm. These orders of magnitude suffice to permit interaction with the corresponding part on which the contact-fastener part is to be fastened by the so-called Van der Waals forces. These so-called Van der Waals forces occur because the negatively charged electrons in an atom moving around the positive core are for a brief period concentrated on one side. As a result, the atom is temporarily negatively charged on this side but positively charged on the other. This also affects adjacent atoms, in this instance the atoms at the ends of the individual fibers of each side. The result is that an individual fiber is attracted either by the positive or negative atoms of the respective opposite surface, depending on the charge which it receives. The larger the contact surface in the total, the stronger are the forces which occur. Although the Van der Waals forces are among the weakest forces in nature, the effect is enough to result in relatively high fastening forces. For example, an appropriately configured surface of a contact-fastener part of the order of magnitude of several square centimeters can lift an indefinite number of kilograms or keep them stationary as a result of the Van der Waals forces on the free ends of the individual fibers of each stalk.

The respective fastener may be very cost effectively produced and generally be detachably connected to any surface (background) in order, for example, to connect a vehicle body part connected to the contact-fastener part to a vehicle frame or to hang a picture directly on a wall by way of the contact-fastener part and without any other connection means, in that the individual fibers of the contact-fastener part interact directly with the surface of the wall through the Van der Waals forces.

If the respective fastener produced by the process claimed for the invention gains entry into the clothing industry, no other modifications are needed. In particular, no fleece or looped material need be accommodated on parts of clothing in order to ensure interlocking with the contact-fastener part. The contact-fastener part may rather interact directly by the free ends of the individual fibers with the material of the clothing material for production of a connection. It has been found that, for the purpose of separation of the contact-fastener part, it is best for the latter to be peeled off from the surface at an angle of approximately 30° in order to be able to release the locking by the Van der Waals forces and remove the fastener from a surface of any nature. The respective fastening and release processes may occur repeatedly, preferably several thousand times, as a function of the configuration of the fastening system. In order to effect fastening it suffices for the free ends of the fibers of the stalks of the contact-fastener part to be applied flatly to the surface. Provision preferably is made such that the length selected for the individual filaments or fibers is such that the free end of each of these stalks ends in a common plane, since the Van der Waals forces exert an effect only over a markedly short distance, so that preferably provision is made such that the distance between the free contact ends of the individual filaments and the surface provided is essentially the same. In order to prevent the individual fibers from breaking away from the surface with which contact is to be made, these fibers preferably are of a length which is less than 10% to 30% of the total stalk length. This makes certain that the stalk forms a support for the individual fibers and thus improves the rigidity behavior of the fibers.

Very good interlocking results have been obtained in experiments when there are about 4,000 stalks per square centimeter of support surface and about 500 individual fibers with a common terminal plane on each free end of such a stalk.

In one preferred embodiment of the process claimed for the invention the stalks are subjected to chemical, mechanical, or electric (heat) treatment for the purpose of separation of the individual fibers from the free ends of the stalks.

Additional advantageous embodiments of the process claimed for the invention are presented in other dependent claims.

The process claimed for the invention is described in detail in what follows on the basis of a contact-fastener part obtained by the process, with reference to the drawing, in which in diagrammatic form and not drawn to scale

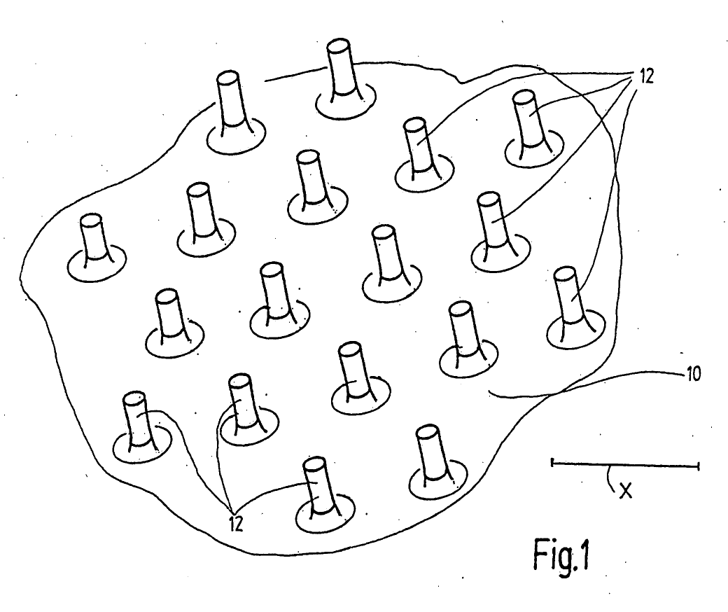

FIG. 1 presents a perspective top view of a section of a part produced by the process claimed for the invention and consisting of a support material and a plurality of stalks mounted on the material and integral with it;

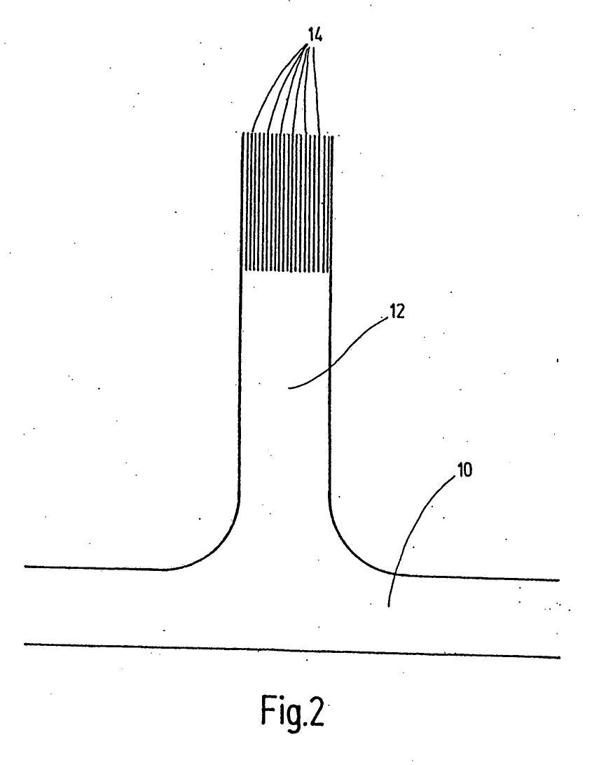

FIG. 2 a side view of a section of the support material with only one stalk having individual fibers mounted on its free end.

The initial product for a contact-fastener part as specified for this invention may be obtained, for example, by a process such as that described in DE 196 46 318 A1. The known process is applied for production of a contact-fastener part having a plurality of interlocking means integral with a support material 10 and in the form of stalks having thickened areas, a process in which preferably a thermoplastic material in the plastic or liquid state is introduced into a gap between a press roller and a shaping roller which is provided with a screen having cavities opening outward and inward and the two rollers rotate in opposite directions for the production process, so that the support material is formed in the gap between the rollers. Since it is sufficient for the contact-fastener part claimed for the invention to produce stalks 12 as the initial product, the known production process is modified so that only the stalks 12 are formed in the shaping cavities of the screen and no head-shaped thickened areas are formed as interlocking means on their free side. This may be effected by suitable selection of the shaping cavity or by control of the process parameters. If, for example, the flowing pattern of the plastic material in the screen cavity is controlled, the flowing pattern of the plastic material may be reduced, and, because of the surface tension of this material, stalks 12 are obtained as the product the free ends of which have a convex or level edge area. The screen cavities may be kept at a low temperature level for this purpose. For example, they may be cooled or the plastic material is introduced into the shaping cavities at a lower injection temperature.

DE 100 65 819 C1 describes another option for obtaining the stalk fastener part shown in FIG. 1. In this known process a support material is provided over at least a part of its surface with contact-fastener parts projecting from the plane of the surface, a plastic material forming the contact-fastener parts being applied to the support element and the contact-fastener parts being configured free of a molding tool over at least part of their area and the plastic material being deposited in consecutive drops by means of at least one application device. Although the application device spreads the plastic material by way of its nozzle in drops of a volume of only a few picoliters, a rapid process may be conducted so that the stalk material shown in FIG. 1 is obtained in a very short time. Under these conditions as well care is taken in the application of the process to make certain that only cylindrical stalks with more or less planar head sides are obtained from the drops. The possibility also exists of producing the stalk strip shown in FIG. 1 by finish calendering, by way of a calender roll not shown, of pointed or tapered stalk elements on the head side in a shaping roller, for example, at a temperature in the mold softening range, in order to obtain planar head ends for the individual stalks of the contact-fastener part.

The process indicated in the foregoing may be applied to readily obtain 1,000 to 10,000 stalks 12 per square centimeter of support surface 10; a stalk count of about 4,000 per square centimeters of support surface 10 has been found to be adequate. To give an idea of the size relationships, a length X corresponding to a size of 200 μm has been plotted on the lower right side of the illustration as viewed in the direction of FIG. 1. The length of the stalk drawn on a larger scale in FIG. 2 as measured from the free end of the stalk to the support surface is about 140 μm and the diameter about 33 μm, this corresponding to an aspect ratio of about 5:1.

The stalk end in question is divided in a subsequent step of the production process into a plurality of individual fibers 14; by preference each stalk has approximately 500 filaments with a diameter of 0.2 μm on each stalk 12. In addition, care is taken to ensure that the length of the individual fibers 14 represents about 20% of the total length of the stalk 12, including the individual fibers 14. Each individual fiber 14 accordingly has its length held securely by the remaining stalk length and the remaining stalk cross-section thus forms a support for the individual fibers 14 in order to have them kept in place on a definable surface by the Van der Waals forces. It is also important for this purpose that the free ends of the individual fibers 14 be positioned side by side in a plane which, as is shown in FIG. 2, extends in parallel with the support surface 10 of the support material for the contact-fastener part.

The carrier 10, the individual stalks 12, and the individual fibers 14 of each stalk consist of a plastic material, one selected in particular from the group of acrylates such as polymethacrylates, polyethylene, polypropylenes, polyoxymethylenes, polyvinylidene fluoride, polymethylpentene, polyethylene chlorotrifluoroethylene, polyvinyl fluoride, polyethylene oxide, polyethyleneterephthalates, polybutyleneterephthalates, nylon 6, nylon 66, and polybutene. Plastics with long molecule chains and good orientation patterns have been proved to be especially good.

In order to obtain the individual fibers 14 now from the stalk 12 it is necessary to act on the respective ends of the stalks 12 in one step of the production process. One mechanical separation option is represented by the possibility of using blades such as ceramic microblades to cut the ends of the stalks to a specific length to obtain the individual fibers 14. Other options are brushing or whipping the ends of the stalks in order to obtain individual filaments or fibers. Other mechanical separation means are represented by pulsed water streams, and the possibility also exists of using special laser assemblies to carry out the cutting or division process. If energy application means are applied to the stalks, means such as aluminum or silicon dioxide, the possibility also exists of separating the stalk ends by applying energy such as ultrasound, infrared heat, or the like to strike the ends and initiate separation. Chemical etching processes may also yield the required plurality of individual filaments.

Not only do the contact-fastener part and the process involved permit revolutionary use of Van der Waals bonding forces to effect bonding of the contact-fastener part to any surfaces, but it has also been found that the contact fastening in question exerts a self-cleaning action similar to the lotus effect, and, because of the micro-nature of the fastener part and the use of materials with low surface energy, it is ensured that fouling particles, especially ones in liquid form, will bead off from the artificial fastener surface and not foul it. This justifies the expectation that the contact-fastener part claimed for the invention will have a long service life.

1. A method for producing a contact-fastener part, in which a support (10) is manufactured having a plurality of stalks (12) by preference integrated with it, characterized in that in the contact-fastener part at least some of the free ends of the stalks (12) are provided with a plurality of individual fibers (14).

2. The process as claimed in claim 1, wherein the respective stalk (12) is divided on its free end into a plurality of individual fibers (14) which end in a common plane, by preference on their free ends.

3. The process as claimed in claim 2, wherein the length of the individual fibers (14) is less than one-half, by preference 10 to 30%, of the total stalk length.

4. The process as claimed in claim 1, wherein approximately 1,000 to 10,000 stalks (12), in particular 3,000 to 6,000, and by preference approximately 4,000 stalks, are provided per square centimeter of support surface, and wherein 50 to 5,000, by preference approximately 500, individual fibers (14) are provided per stalk.

5. The process as claimed in one of claim 1, wherein, for the purpose of division of the individual fibers (14) from the free end of the stalks (12), such stalks (12) are subjected to chemical, mechanical, or electric (heat) treatment.

6. The process as claimed in claim 1, wherein the support (10), the stalks (12), and the individual fibers (14) consist of a plastic material selected in particular from the group of acrylates such as polymethacrylates, polyethylene, polypropylenes, polyoxymethylenes, polyvinylidene fluoride, polymethylpentene, polyethylene chlorotrifluoroethylene, polyvinyl fluoride, polyethylene oxide, polyethyleneterephthalates, polybutyleneterephthalates, nylon 6, nylon 66, and polybutene.

7. The process as claimed in claim 1, wherein that the support (10) with its stalks (12) is obtained from a mold rolling process, a calendering process, or by a droplet deposition process free of molding tools.

8. The process as claimed in claim 7, wherein the adjustment parameters for the individual processes for obtaining the stalks (12) are set so that more or less cylindrical stalks (12) with planar head ends on their front side are obtained.
